(19) United States
(12) Patent Application Publication
(10) Pub. No.: US 2006/0005875 A1
(43) Pub. Date: Jan. 12, 2006

(54) Modular plug-in apparatus and method for safe and secure storage of horizontally stacked photovoltaic modules during transport

(76) Inventor: Joachim Haberlein, Pfungstadt (DE)

Correspondence Address: PRICE HENEVELD COOPER DEWITT & LITTON, LLP, 695 KENMOOR, S.E., P O BOX 2567, GRAND RAPIDS, MI, 49501, US

(21) Appl. No.: 11/182,939

(22) Filed: Jul. 12, 2005

(30) Foreign Application Priority Data
Jul. 12, 2004 (EP) 04 016 311.5

(51) Int. Cl. H01L 31/00

(52) U.S. Cl. 136/251; 136/291

(57) ABSTRACT

A modular apparatus and method for safely and securely storing horizontally stacked photovoltaic modules includes a plurality of molded, plug-in components. Each of the components has an inwardly facing load-bearing support portion configured to abuttingly supporting thereon a photovoltaic module, a lower portion with at least one downwardly extending projection, and an upper portion with at least one cavity shaped to closely receive therein said projection on a vertically adjacent one of said components, such that the components are stacked in a vertical column to support portions of the horizontally stacked photovoltaic modules.

### CLAIM OF PRIORITY

Applicant hereby claims the priority benefits under the provisions of 35 U.S.C. § 119, basing said claim of priority on European Patent Application Serial No. 04 016 311.5, filed Jul. 12, 2004. In accordance with the provisions of 35 U.S.C. § 119 and Rule 55(b), a certified copy of the above-listed European patent application will be filed before grant of a patent.

### BACKGROUND OF THE INVENTION

The invention relates to a modular plug-in apparatus and method for the safe and secure storage of horizontally stacked photovoltaic modules during transport.

As a result of the populace's changed energy awareness and supported by government-sponsored initiatives, the utilization of renewable energy sources has increasingly gained importance; this is particularly the case in the area of photovoltaic modules, and the conversion of sunlight into electricity. In a lot of places, not just in Germany, efficient, state-of-the-art equipped companies have been formed, at which photovoltaic modules are currently manufactured as mass-produced articles, using the most rational processes, to be shipped to all parts of Europe and the world.

Considerations regarding innovative rationalization must not be limited to only manufacturing technology criteria, but must also encompass the areas of shipping and packaging safety.

Photovoltaic modules (PV modules) in their standard form consist of a front sided, single-pane safety glass pane, typically 4 mm thick, two layers of transparent laminate foil, fused together, between which the photovoltaic cells, typically made from silicone, as well as an electrical conduit system, are embedded, and a special plastic foil that seals the back side vapor diffusion tight. This is referred to as glass/plastic modules. The back side may instead also be equipped with a pane of glass (glass/glass modules).

In most cases, the standard PV modules are equipped with a frame made of a drawn aluminum profile, for example with a frame depth of 42 mm. In rarer cases, however, frameless PV modules are also shipped, both those that are carried out as glass/plastic modules as well as those executed as glass/glass modules.

The size of standard PV modules generally ranges from 0.8 to 1.6 m². The weight of framed modules typically is between 14 and 28 kg. Glass/glass modules are approximately 60 percent heavier.

PV modules typically are packaged individually in cardboard and stacked horizontally on wooden pallets for transport to the customer. To secure a stack of individual packages against slipping, it is connected to the pallet by means of tightening straps.

The general method of shipment packaging of the PV modules described herein has several significant disadvantages. For one, stacking is only possible up to a limited stack height, since the added weight load of the stacked modules is all transferred to the modules that are located at the bottom.

In addition to the static load, dynamic load stress occurs during transport, for example when a hard set down by the fork lift occurs, or when there are acceleration, deceleration and centrifugal forces during transportation on a truck and especially vibrations from driving over ties and pot holes. When stacked too high, all this can easily cause damage to the bottommost module or modules.

Packaged PV modules therefore are rarely shipped in stack heights of more than 1 m. Due to the risk of overloading the modules located at the bottom, it is also not possible to stack two loaded pallets on top of each other. As a result, the loading height of a truck's storage space quite often can be used only partially.

In addition, the unpacking of the individually cardboarded modules causes a significant amount of work to the end user. On top of that, there is finally the thankless task of collecting significant amounts of cardboard at the installation site, and, if necessary, cutting them down and introducing them to paper recycling.

### SUMMARY OF THE INVENTION

The considerations presented herein result in the task according to the invention of creating a packaging and/or shipping safeguard [safety] system for PV modules that guarantees safe and secure shipping even at high stack heights, eliminates the risk of damage to the bottommost located modules, renders individual packaging of modules with cardboard superfluous and reduces the packaging needs overall to the minimum necessary, which consist of very sturdy individual elements that are cost effective to produce, and, whenever possible, are uniformly shaped and made up of small, highly stable individual components that can be shipped back to the module manufacturer to be reused through numerous cycles.

To solve this problem, the invention suggests a modular plug-in system for safe and secure storage of horizontally stacked photovoltaic modules during shipping, wherein the system builds load-bearing, i.e., load-reducing, columns made from molded form components, wherein each of these molded form components is equipped with an inwardly facing, load-bearing profile to accommodate and support the photovoltaic module upwardly and/or downwardly with one of more dowels or a tongue and upward and/or downward facing with one of more open cavities to accommodate the dowel(s) true to size or with a groove to accommodate the tongue. For ergonomic reasons, the respective molded form component is equipped with the dowel(s) or the tongue on its upper side and with the cavities open to the bottom or the groove at the bottom.

The plug-in system according to the invention therefore features load-bearing columns that are statically independent of each other, consisting of small sized, molded form components.

The load-bearing profile can support the photovoltaic modules at any position, for instance at their sides. It is, however, considered to be advantageous, especially considering the background of photovoltaic modules, which have a rectangular shape, to place the load-bearing profiles as supports for each of the four corners of the rectangular photovoltaic modules. It must be particularly assured that the profiles constitute slip-proof supports for the photovoltaic modules.

Therefore, a system of four load-bearing, load-reducing columns, particularly four load-bearing, [and thus] load-reducing corner columns, is suggested. Four columns are arranged at the four corners of the modules to be stacked, whose purpose it is to bear the additional weight load of the PV modules and to transfer said load outside of the PV modules to a bearing pallet.

The four columns show modular, uniformly shaped molded form components. Each component serves the purpose of accommodating a quarter of the weight load of each PV module and transfering it to the column. Each module is connected to the neighboring module via a simple mechanical plug and socket connection.

Therefore, the modular molded form components, when plugged together, form a heavy-duty load-bearing column. The slip-proof connection each molded form component forms with the neighboring component is achieved via a plug and socket connection, for example via a dowel cavity construction. Each of the molded form components is inwardly facing, and equipped with the load-bearing support profile into which the PV module is placed true to size, especially in the area of each respective corner. There are only comparatively low weight and dynamic loads impacting the support profile.

Due to an advantageous design, the molded form components have a rectangularly angled shape. Due to an advantageous, alternative design, it is intended that the molded form components build a round load-bearing column when connected. The plug and socket connection is accomplished by means of a single dowel and a single cavity. In addition to the angular or round shape of the load-bearing column, triangular, rectangular or polygonal shapes are also possible.

Additional characteristics of the invention are detailed in the sub-claims that are described below, which particularly refer to the description of the figures, as well as in the figures themselves, whereby it is noted that each individual characteristic and all combinations of individual characteristics are additional characteristics according to the invention.

### BRIEF DESCRIPTION OF THE DRAWINGS

The invention is described in the figures on the basis of multiple embodiment examples, without being limited to those. Shown are, in:

FIG. 1 a first embodiment of a molded form component, in a spatial view diagonally up from the bottom;

FIG. 2 the molded form component depicted in FIG. 1, in a spatial view diagonally from the top;

FIG. 3 two molded form components in accordance with the embodiments of FIGS. 1 and 2, plugged onto each other, wherein the lower molded form component accommodates a rectangular photovoltaic module, of which only a corner is shown, in the area of a single corner;

FIG. 4 a cross section through the setup made in FIG. 3;

FIG. 5 a second embodiment of a molded form component;

FIG. 6 a setup of two molded form components in accordance with a third embodiment; and

FIG. 7 a fourth embodiment of a molded form component.

### DETAILED DESCRIPTION OF THE PREFERRED EMBODIMENTS

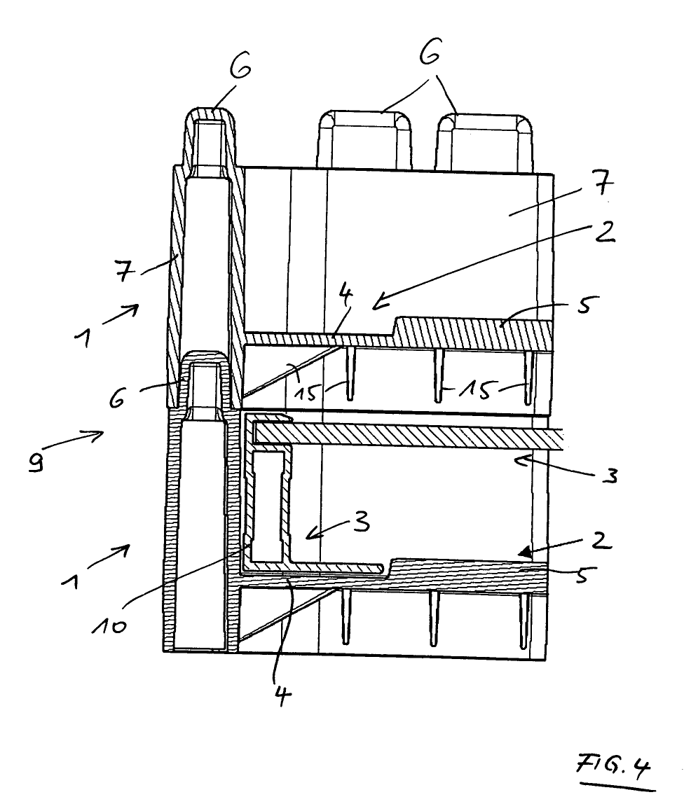

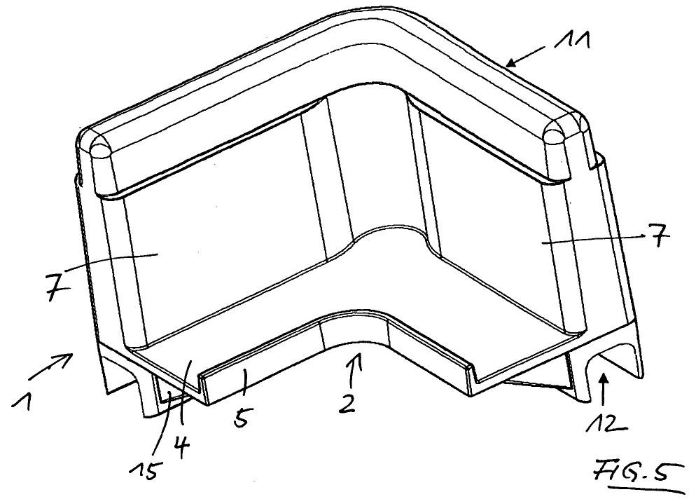

For purposes of description herein, the terms “upper”, “lower”, “right”, “left”, “rear”, “front”, “vertical”, “horizontal” and derivatives thereof shall relate to the invention as oriented in FIGS. 3 and 4. However, it is to be understood that the invention may assume various alternative orientations and step sequences, except where expressly specified to the contrary. It is also to be understood that the specific devices and processes illustrated in the attached drawings, and described in the following specification, are simply exemplary embodiments of the inventive concepts defined in the appended claims. Hence, specific dimensions and other physical characteristics relating to the embodiments disclosed herein are not to be considered as limiting, unless the claims expressly state otherwise.

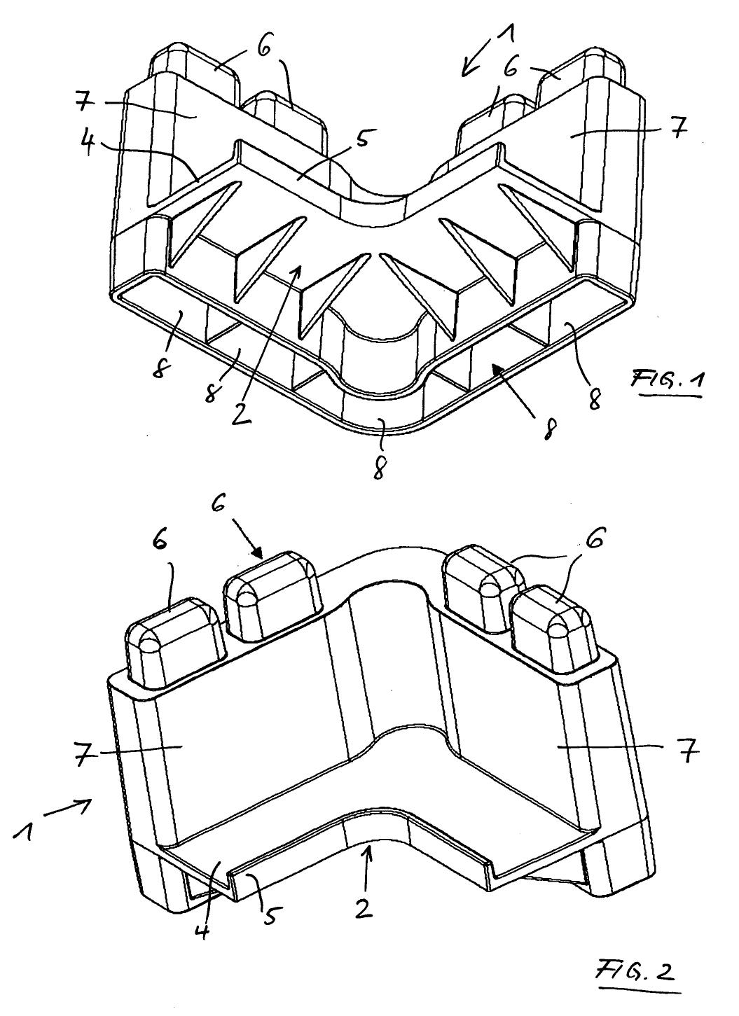

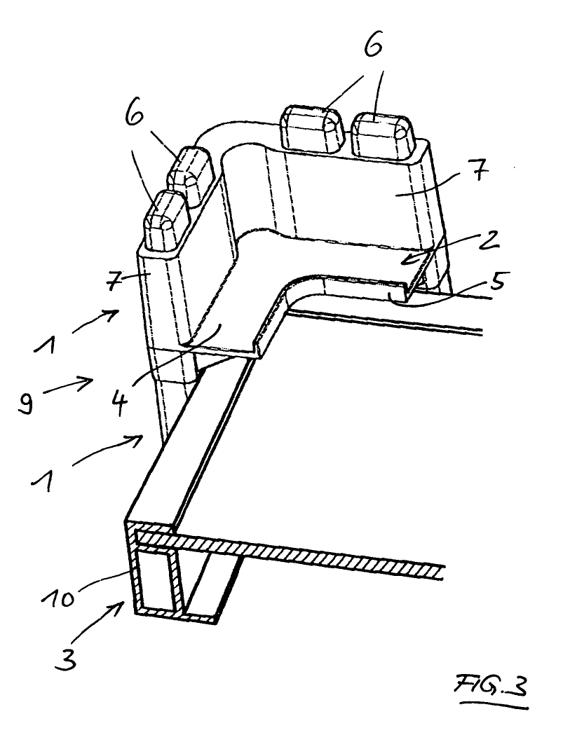

The molded form component 1 depicted in FIGS. 1 to 4 respectively for example is formed out as a plastic injection mold component and has a rectangular form. The molded form component 1 is inwardly facing, and equipped with a load-bearing support profile 2 as a means of support for the photovoltaic module 3. The support profile 2 essentially is formed by a horizontal panel section 4, as well as a vertical, upwardly facing border section 5 in the area of the inner end of the panel section. On its top side, the molded form component 1 features four dowels 6, wherein each side section 7 of the rectangular molded form component 1 has two dowels 6 assigned. On its bottom side, the molded form component 1 is equipped with multiple downwardly facing open cavities 8, wherein the four cavities 8, which are assigned to the side sections 7, serve to accommodate the four dowels 6 of the molded form component located underneath.

A heavy-duty load-bearing column 9 can be constructed from a large number of molded form components 1, which in FIGS. 3 and 4 only is exemplified with regards to two molded form components 1 that are plugged into each other. The slip-proof connection of each molded form component 1 with the neighboring molded form component 1 is achieved via the plug and socket mechanics, which in this example of execution are implemented via the dowel cavity construction. The modular plug-in system forms four load-bearing, load-reducing corner columns 9, wherein the PV module 3 with its four corners can be fit true to size into the support profile 2 of the load-bearing column 9.

The execution of the inwardly facing support profile 2 of the molded form component 1 depends on whether the modular plug-in system according to the invention is intended for the safe shipping of framed or unframed PV modules 3.

FIGS. 3 and 4 depict the example of a molded form component 1 which is intended to accommodate the corner of a framed PV module 3. The inwardly facing support profile 2 can take up all of the horizontal support surface 4, the width of which is matched to the width of the back side frame profile 10 in the corner area of the PV module 3 to be placed upon. The vertical border area 5 functions as a vertical expansion protection and guarantees the true to size fit of the frame's corner with only minimal allowance. The vertical distance between the horizontal support profile of a molded form component 1 and the support profile of the neighboring molded form component 1 is defined by the thickness of the framed PV module 3 plus the average thickness of a human fingertip. This guarantees that individual PV modules 3 can be lifted off of the stack effortlessly.

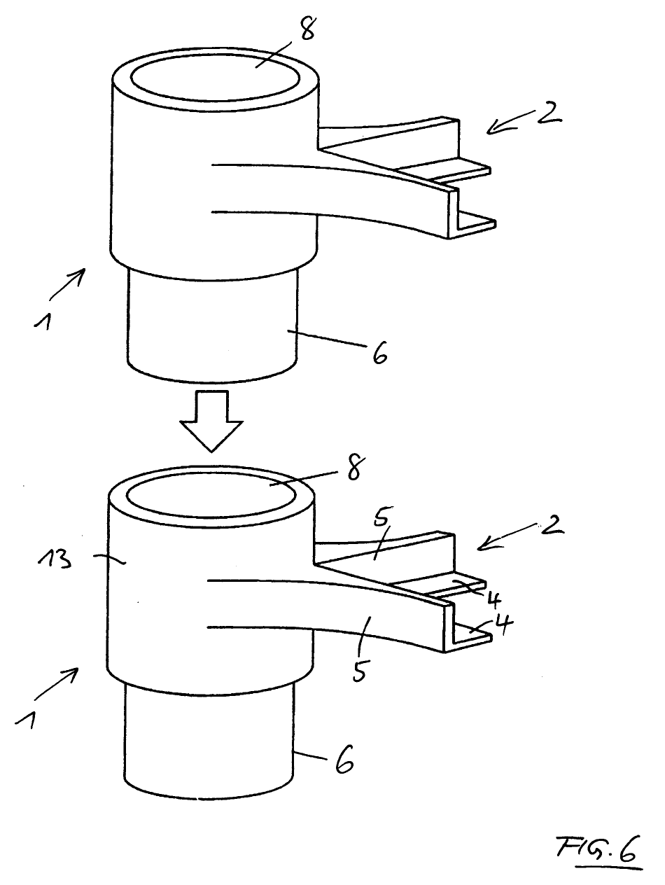

FIG. 5 illustrates another sensible execution of the modular plug-in system according to the invention, in which the basic design of the molded form component 1 corresponds to the embodiment of the molded form component 1 of FIGS. 1 to 4. However, in the embodiment of FIG. 5, the design shows, instead of the four dowels 6 on top, a continuous and therefore rectangular tongue 11, and instead of the lower cavities 8, a continuous, angled groove 12. When plugging the molded form components into each other, the groove 12 of the upper molded form component 1 plugs into the tongue 11 of the lower molded form component 1.

For the dowel cavity plug connections, as well as for the tongue and groove connections, it is advantageous for the operation of the system if the dowels or tongues are slightly conically-shaped and if the edges are rounded or beveled.

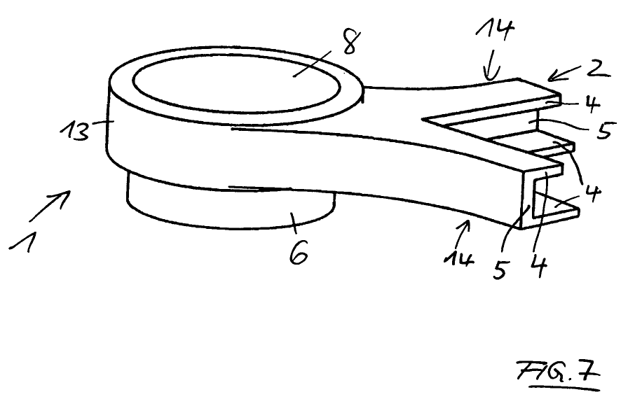

The depicted rectangularly angular form of the molded form components in the figures discussed thus far, represents a sensible, but not the only possible, component form of the modular plug-in system according to the invention for ensuring a safe shipment of stacked PV modules. Another advantageous design of the molded form components is illustrated in FIGS. 6 and 7.

FIG. 6 shows two molded form components 1 which, when plugged together, form a round load-bearing column. The plug connection occurs by means of a single lower dowel 6 and a single upper cavity 8 respectively. In addition to the angular or round design shape of the column, triangular, rectangular or polygonal forms are also possible.

In the embodiment according to FIG. 6, the molded form component 1 is also formed out of a plastic injection mold component. The support profile 2 features the lower panel section 4, as well as the outer vertical border section 5 representing the connection to the hollow cylinder section 13 of the molded form component 1. The outer diameter of the dowel 6 is matched to the inner diameter of the hollow cylinder section 13, so that the dowel 6 can be inserted into the cavity 8 of the neighboring molded form component 1 with little tolerance.

The support profile 2 in accordance with the embodiment example of FIG. 6 may also accommodate the corner of an unframed PV module 3.

FIG. 7 shows the example of a molded form component 1 that is designed to accommodate the corner of an unframed PV module. The inwardly facing support profile 2 herein is formed out in the shape of two parallel cross corner horizontal bars 14. The corner of the unframed PV module is placed between the two bars 14.

For a secure load transfer from the horizontal support profile 2 to the load-bearing column, the support profile should be designed to feature a thicker wall in the transition area from the horizontal to the vertical than in the horizontal load-bearing area. This is illustrated particularly for the embodiments in accordance with FIGS. 1 to 4. It shows a material and weight saving design. Herein, the support profile 2 is formed out of relatively thin walls, but is supported at the bottom with vertical stiffening ribs 15.

The molded form components themselves may also have a material saving design, in that they have additional vertical cavities open to the bottom, in addition to those open cavities necessary to accommodate the dowels.

Additional optional design characteristics of the modular plug-in system according to the invention are that, in particular with respect to angular load-bearing columns, all vertical edges of the molded form components are rounded or beveled to protect them from “being smacked into” during loading and unloading under very narrow conditions, and the molded form components are equipped on top with a groove or beveled edge to accommodate or guide tightening straps.

Another component of the invention is the option to complement the load-bearing column system of molded form components by base components, particularly to complement the four columns by three base components. Such a base component serves for adjusting a column or its bottom component on the pallet.

The base component consists of a small sized plate, which on its top side is equipped with one or more dowels or a tongue and on its bottom side with corresponding cavities open to the bottom or a groove. The plate of the base component has holes so that it can be nailed or screwed to the pallet.

Due to this design, the base component is also suitable for plugging into the top molded form component, so that, in case of stacking of two loaded pallets on top of each other, the fit to size setting down of the second pallet is eased.

All parts of the invented modular plug-in system can be advantageously manufactured in an injection molding process and consist of filler-free or mineral-filled thermoplastic plastic, or alternatively, they can be manufactured of light metal.

### EXAMPLES

For the application of the invented modular plug-in system and its advantages:

### Example #1

Problem:

One hundred and fifty framed standard PV modules with a surface of 1 m² each are suppose to be packaged and shipped safely from the module manufacturer to the customer.

A: Problem Solution Using Traditional Packaging Methods

Steps:

Each of the 150 PV modules is individually packaged using cardboard and adhesive tape. A maximum of 15 individually packaged modules are stacked flush on a wooden pallet (no standard pallet, but rather a customary special pallet, which is fit to the surface measurements of the product). The loaded pallet is secured with tightening straps. The height of each of the ten stacks on pallets is approximately 90 cm.

Result:

The time for each of the three steps, with regard to 150 PV modules, totals five man hours. The amount of packaging material used (without adhesive tape and without tightening strap) amounts to ten pallets and approximately 330 m² of cardboard.

B: Problem Solution Utilizing the Invented Modular Plug-In System

Steps:

Four of the molded form components according to the invention are placed on the corner areas of the special pallet. The molded form components are inwardly facing, and equipped with a support profile for the precisely fitted insertion of the back side frame profile into the corner area of the framed PV module. (cf. FIGS. 1-4) A first (unpackaged) PV module is hooked/placed into the molded form components. Then another four molded form components are plugged onto the lower molded form components. Then the next (unpackaged) PV module is latched in. Another four molded form components are plugged onto the molded form components located underneath. The next (unpackaged) PV module is latched in. The simple process is repeated until 25 PV modules per pallet are latched into the four column system formed by the molded form components and the stack height (including pallet) is approximately 160 cm. Each of the six palleted stacks formed this way is cardboarded and secured with a tightening strap.

Result:

The time for each of the steps, with regard to 150 PV modules, amounts to 1.25 man hours. The consumption of packaging materials (without tightening strap) amounts to six pallets and approximately 45 m² of cardboard. Additionally there are 600 invented molded form components which are retrieved via the deposit system and can be reused approximately 50 times.

C: Result Comparison Between A and B

The use of the modular plug-in system according to the invention saves 3.75 man hours, four wooden pallets and approximately 280 m² of cardboard in comparison to the traditional packaging for shipment. This is countered by an additional material requirement of 600 reusable molded form components according to the invention. With a 50 time recirculation, this is equivalent to a material consumption of 12 molded form components.

### Example #2

Problem:

Unframed standard PV modules shall be packaged safely for shipment to transport the module from the manufacturer to the customer.

Steps:

The traditional packaging method essentially is equivalent to Version A of Example #1.

Result:

When applying the modular plug-in system according to the invention, the problem is solved by using molded form components whose support profile is formed out in the shape of two parallel running, cross corner horizontal bars (cf. FIG. 7). In this case, at first, three such molded form components are pushed over the four edges of the unframed PV module and then are placed together with the PV module onto the pallet or are subsequently plugged into the upwardly growing four column stack. The advantages in regard to time and packaging material savings are essentially equivalent to Example #1.

### Example #3

Problem:

The loading height of a truck shall be used by stacking two palleted stack packages on top of each other.

When using the traditional packaging method (described in Example #1), this problem cannot be solved, since the individually packaged PV modules located on the bottom pallet would be overstressed by the load bearing down from the second pallet stack. The risk that the PV modules located at the bottom in particular will be damaged by the dynamic loads occurring during transport would be very high.

Result:

The use of the modular plug-in system according to the invention in contrast allows for the stacking of two palleted stacks (i.e., 1 m high each), since the four column construction formed from molded form components is designed for correspondingly high loads.

### Example #4

Problem:

Twenty PV modules with a surface of 1 m² each shall be taken off the pallet and/or unpacked at the installation site.

A: Problem Solution Using Traditional Packaging Method

Steps:

The PV modules, individually cardboarded, are delivered on two pallets. The tightening straps are removed, each module is unpacked individually.

Result:

Two pallets and approximately 45 m² of cardboard have to be disposed of.

B: Problem Solution Using the Invented Modular Plug-In System

Steps:

The PV modules are delivered on a single pallet unit, cardboarded in its totality. The tightening straps and the cardboard are removed. The unpackaged PV modules are individually lifted off. The molded form components of the load-bearing columns are successively “picked” and dropped into a small accompanying carton for retrieval and reuse.

Result:

One pallet and approximately 6 m² of cardboard have to be disposed of.

In the foregoing description, it will be readily appreciated by those skilled in the art that modifications may be made to the invention without departing from the concepts disclosed herein. Such modifications are to be considered as included in the following claims, unless these claims by their language expressly state otherwise.

The invention claimed is as follows:

1. A modular apparatus for safely and securely storing horizontally stacked photovoltaic modules, comprising:
a plurality of molded, plug-in components, each having an inwardly facing load-bearing support portion thereof configured for abuttingly supporting thereon a photovoltaic module, a lower portion thereof with at least one downwardly extending projection, and an upper portion thereof with at least one cavity shaped to closely receive therein said projection on a vertically adjacent one of said components, whereby said components are stacked in a vertical column to support portions of the horizontally stacked photovoltaic modules.

2. An apparatus as set forth in claim 1, including:
four stacked vertical columns of said components arranged at opposite corners of the horizontally stacked photovoltaic modules.

3. An apparatus as set forth in claim 2, wherein:
said columns of vertically stacked components are arranged in a rectangular plan configuration.

4. An apparatus as set forth in claim 1, including:
a base plate having at least one upstanding projection shaped for close reception in said cavity of a vertically adjacent one of said components, and a bottom surface configured for fastening to an associated pallet.

5. An apparatus as set forth in claim 4, wherein:
said components each have a generally L-shaped plan configuration.

6. An apparatus as set forth in claim 5, wherein:
each of said components has a substantially identical size and shape.

7. An apparatus as set forth in claim 6, wherein:
said inwardly facing load-bearing support portion includes a horizontally extending panel having an outer edge with an upstanding border extending therealong.

8. An apparatus as set forth in claim 7, wherein:
said projection comprises a plurality of dowels, each having a generally rectangular plan shape.

9. An apparatus as set forth in claim 7, wherein:
said projection comprises a tongue having an L-shaped plan shape; and
said cavity comprises a groove having an L-shaped plan shape configured to closely receive said tongue therein.

10. An apparatus as set forth in claim 7, wherein:
said component includes a side section having a generally rectangular vertical cross-sectional shape.

11. An apparatus as set forth in claim 7, wherein:
said component includes a side section having a generally circular horizontal cross-sectional shape.

12. An apparatus as set forth in claim 6, wherein:
said inwardly facing load-bearing support portion includes a pair of vertically spaced apart, horizontally extending bars between which a corner of an unframed one of the photovoltaic modules is received.

13. An apparatus as set forth in claim 12, wherein:
said inwardly facing load-bearing support portion includes vertical ribs disposed along a lower portion thereof.

14. An apparatus as set forth in claim 6, wherein:
said projection is shaped generally conically.

15. A method for safely and securely storing horizontally stacked photovoltaic modules, comprising:
molding a plurality of plug-in components, each having an inwardly facing load-bearing support portion thereof configured for abuttingly supporting thereon a photovoltaic module, a lower portion thereof with at least one downwardly extending projection, and an upper portion thereof with at least one cavity shaped to closely receive therein said projection on a vertically adjacent one of said components;
positioning a portion of a first one of the photovoltaic modules on the support portion of a first one of the components;
stacking a second one of the components on top of the first component by inserting the projection on the first component into the cavity on the second component; and
positioning a portion of a second one of the photovoltaic modules on the support portion of the second component.

16. A method as set forth in claim 15, including:
positioning four stacked vertical columns of the components at opposite corners of the horizontally stacked photovoltaic modules.

17. A method as set forth in claim 16, including:
arranging the columns of vertically stacked components in a rectangular plan configuration.

18. A method as set forth in claim 17, wherein:
said molding step comprises forming the components in a generally L-shaped plan configuration, and a substantially identical size and shape.

19. A method as set forth in claim 18, wherein:
said molding step includes forming the inwardly facing load-bearing support portion with a horizontally extending panel having an outer edge and an upstanding border extending therealong.

20. A modular stacking apparatus, comprising:
a plurality of photovoltaic modules each having a generally rectangular plan configuration of similar size; and
a plurality of molded, plug-in components, each having an inwardly facing load-bearing support portion thereof configured for abuttingly supporting thereon one of said photovoltaic modules, a lower portion thereof with at least one downwardly extending projection, and an upper portion thereof with at least one cavity shaped to closely receive therein said projection on a vertically adjacent one of said components, whereby said components are stacked in vertical columns along opposite corners of said photovoltaic modules to safely and securely store said photovoltaic modules in a horizontally stacked relationship.
